(19) United States
(12) Patent Application Publication
(10) Pub. No.: US 2017/0005254 A1
(43) Pub. Date: Jan. 5, 2017

(54) THERMOELECTRIC MODULE ASSEMBLY

(71) Applicant: Hyundai Motor Company, Seoul (KR)

(72) Inventors: Ho Chan AN, Hwaseong-si (KR); Jong Ho SEON, Seoul (KR)

(73) Assignee: Hyundai Motor Company, Seoul (KR)

(21) Appl. No.: 14/950,258

(22) Filed: Nov. 24, 2015

(30) Foreign Application Priority Data
Jul. 1, 2015 (KR) 10-2015-0094080

(51) Int. Cl. H01L 35/32

(52) U.S. Cl. CPC H01L 35/325

(57) ABSTRACT

A thermoelectric module assembly may include a thermoelectric module structure including a plurality of thermoelectric elements continuously connected to one another and thermoelectric modules having positive terminals and negative terminals which are connected to the thermoelectric elements, wherein the thermoelectric module is provided in plural and each of the thermoelectric modules is adjacently disposed to each other to have the positive terminals or the negative terminals provided along circumferential portions thereof.

### CROSS REFERENCE TO RELATED APPLICATION

The present application claims priority to Korean Patent Application No. 10-2015-0094080, filed Jul. 1, 2015, the entire contents of which is incorporated herein for all purposes by this reference.

### BACKGROUND OF THE INVENTION

Field of the Invention

The present invention relates to a thermoelectric module assembly, and more particularly, to a thermoelectric module assembly capable of easily connecting between a plurality of thermoelectric modules.

Description of Related Art

A thermoelectric module is configured by continuously connecting a plurality of thermoelectric elements which are formed by bonding between heterogeneous semiconductors and is used to cool or heat a target and convert a temperature change into a current.

In detail, the thermoelectric element is an element using a Peltier effect or a Seebeck effect. Here, the Peltier effect is based on the principle that when heterogeneous semiconductors are bonded to each other and then are supplied with a current, one semiconductor absorbs heat and the other semiconductor emits heat, while the Seebeck effect is based on the principle that when heterogeneous semiconductors are bonded to each other and then each semiconductor is applied to different temperatures, an electromotive force is generated thanks to an unbalance of temperature. By using the above characteristics, a small cooler, and the like generally uses the thermoelectric module. The thermoelectric module is configured to serve as a cooler by attaching a radiator to a heat emitting surface to more increase cooling efficiency of a cooling surface. On the contrary, the thermoelectric module may also configure a power generator generating power using a temperature deviation.

The thermoelectric module may be configured in one or in plural depending on whether it is used to absorb heat, perform heating, or generate power. When the thermoelectric module is used over a wide area, the related art uses a method for increasing a size of one thermoelectric module or expanding applications by connecting a plurality of thermoelectric modules 1 in series with each other as illustrated in FIG. 1.

However, as a power supply wire and a power transmission wire is exposed only in one direction , there has been a problem in that the thermoelectric modules may be disposed only in one direction at the time of connecting the plurality of thermoelectric modules to each other. When an exposure frequency of the wire connecting between the thermoelectric modules is increased, the thermoelectric module may have safety problems such as disconnection and heat injury. Further, there has been a problem in that costs may be increased due to the number of wires for connection.

The information disclosed in this Background of the Invention section is only for enhancement of understanding of the general background of the invention and should not be taken as an acknowledgement or any form of suggestion that this information forms the prior art already known to a person skilled in the art

### BRIEF SUMMARY

Various aspects of the present invention are directed to providing a thermoelectric module assembly capable of assembling thermoelectric modules in various forms by improving assembling performance between a plurality of thermoelectric modules and lowering disconnection occurrence possibility between the thermoelectric modules.

According to an exemplary embodiment of the present invention, there is provided a thermoelectric module assembly, including: a thermoelectric module structure configured to include a plurality of thermoelectric elements continuously connected to one another and thermoelectric modules having positive terminals and negative terminals which are connected to the thermoelectric elements, wherein the thermoelectric module is provided in plural and each of the thermoelectric modules is adjacently disposed to each other to have the positive terminals or the negative terminals provided along circumferential portions thereof.

The thermoelectric module assembly may further include: a conducting module configured to be coupled with the thermoelectric module structure and connect between the positive terminal (+) and the negative terminal (−) of the thermoelectric module.

The conducting module may connect between the positive terminals and the negative terminals provided in a circumferential portion of the thermoelectric module structure.

The thermoelectric module structure may be provided in plural and the conducting module may connect between the positive terminals and the negative terminals provided in different thermoelectric module structures.

The thermoelectric module assembly may further include: a connector connecting between the terminal of the thermoelectric module and the conducting module, wherein both ends of the connector are each coupled with the terminal of the thermoelectric module or the terminal of the conducting module, and at least any one of both ends may be detachably coupled with the thermoelectric module structure or the conducting module.

One end of the connector may be formed in a ball shape and the terminal of the thermoelectric module or the terminal of the conducting module into which the one end of the connector is inserted may be formed in a housing shape of which the one side is opened to accommodate and enclose the connector.

The terminal of the thermoelectric module or the terminal of the conducting module into which the one end of the connector is inserted may be provided with an elastic protrusion which is deformed at the time of the insertion of the one end of the connector, elastically recovered after the insertion, and then pressed to prevent the one end of the connector from being separated.

The other end of both ends of the connector may be formed in a T shape and may be rotatably coupled to the thermoelectric module terminal or the conducting module terminal.

The thermoelectric module structures may be integrally formed by bonding side portions of each thermoelectric module to each other and have a polygonal circumferential portion, and one of a plurality of four sides may be provided with the positive terminals and the negative terminals and each terminal may be a terminal belonging to different thermoelectric modules.

The conducting module may be coupled with the positive terminal and the negative terminal of the thermoelectric module structure and each terminal may be terminals belonging to different thermal modules.

The methods and apparatuses of the present invention have other features and advantages which will be apparent from or are set forth in more detail in the accompanying drawings, which are incorporated herein, and the following Detailed Description, which together serve to explain certain principles of the present invention.

### BRIEF DESCRIPTION OF THE DRAWINGS

FIG. 1 is a diagram illustrating a plurality of thermoelectric modules connected to one another according to the related art;

FIG. 2 is a configuration diagram of a thermoelectric module assembly according to an exemplary embodiment of the present invention;

FIG. 3 is a diagram illustrating a thermoelectric module structure according to the exemplary embodiment of the present invention;

FIGS. 4A and 4B are diagrams illustrating a connector according to an exemplary embodiment of the present invention;

FIGS. 5A, 5B and 5C are diagrams illustrating a coupling appearance between a connector and a terminal; and

FIG. 6 is a diagram illustrating a utilization example of the thermoelectric module assembly according to the exemplary embodiment of the present invention.

It should be understood that the appended drawings are not necessarily to scale, presenting a somewhat simplified representation of various features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DESCRIPTION OF THE EXEMPLARY EMBODIMENTS

Reference will now be made in detail to various embodiments of the present invention(s), examples of which are illustrated in the accompanying drawings and described below. While the invention(s) will be described in conjunction with exemplary embodiments, it will be understood that the present description is not intended to limit the invention(s) to those exemplary embodiments. On the contrary, the invention(s) is/are intended to cover not only the exemplary embodiments, but also various alternatives, modifications, equivalents and other embodiments, which may be included within the spirit and scope of the invention as defined by the appended claims.

Hereinafter, a thermoelectric module assembly according to exemplary embodiments of the present invention will be described with reference to the accompanying drawings.

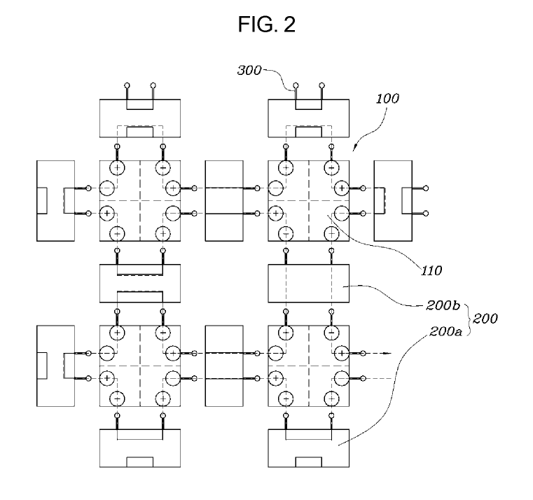

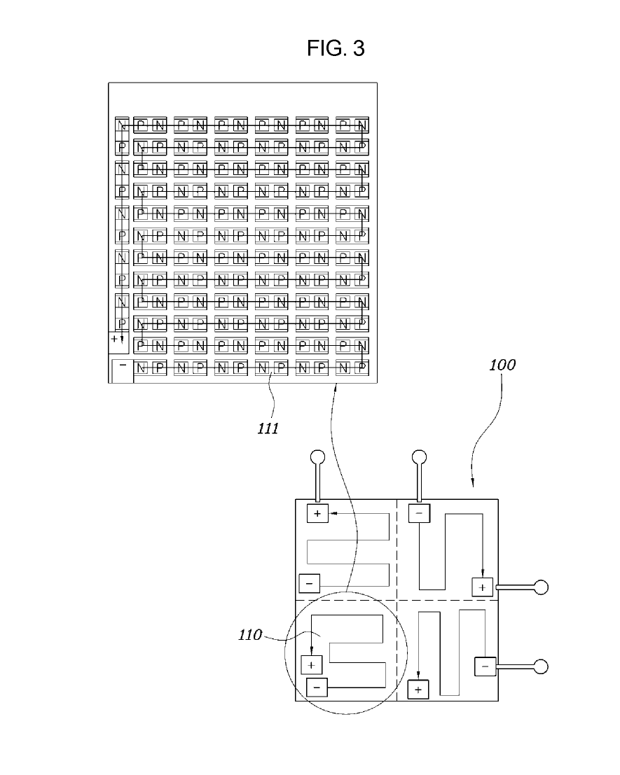

FIG. 2 is a configuration diagram of a thermoelectric module assembly according to an exemplary embodiment of the present invention and FIG. 3 is a schematic cross-sectional view illustrating a thermoelectric module structure according to the exemplary embodiment of the present invention. The thermoelectric module assembly according to the exemplary embodiment of the present invention includes a thermoelectric module structure 100 configured to include a plurality of thermoelectric elements 111 continuously connected to one another and thermoelectric modules 110 having positive terminals (+) and negative terminals (−) which are connected to the thermoelectric elements as illustrated in FIG. 2, in which the thermoelectric module 110 is provided in plural and each of the thermoelectric modules 110 is adjacently disposed to each other to have the positive terminals or the negative terminals provided along circumferential portions thereof.

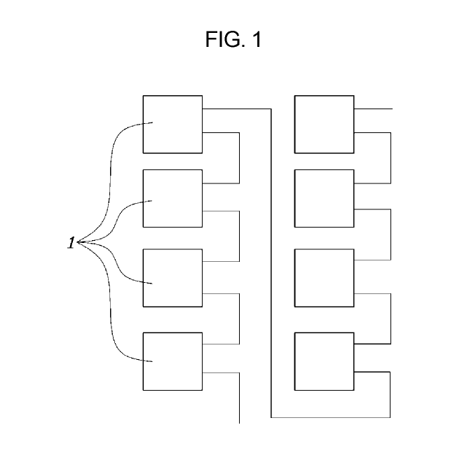

Further, as illustrated in FIG. 1, the thermoelectric module assembly may further include a conducting module 200 which is coupled with the thermoelectric module structure 100 and connects between the positive terminal (+) and the negative terminal (−) of the thermoelectric module 110.

In detail, as illustrated in FIG. 3, the thermoelectric module structure 100 is a structure in which side portions of each thermoelectric module 110 are bonded to one another to be integrally formed and each thermoelectric module 110 may be formed to have different arrangements of thermoelectric elements 111 or have an arrangement of the thermoelectric elements in which some or all of the thermoelectric module 110 are same. As described above, each thermoelectric module 110 may have positive terminals (+) and negative terminals (−) separately from other thermoelectric modules. Preferably, the terminals of each thermoelectric module 110 are arranged along a circumferential portion of the thermoelectric module structure 100 and thus the thermoelectric module structure 100 may have a coupling relationship with the conducting module 200.

Each thermoelectric module 110 may be formed in various forms, but preferably may be formed in a polygonal shape. More preferably, the thermoelectric module structure 100 may also be formed in various shapes but may be formed to have a polygonal circumferential portion.

As the thermoelectric module structure 100 is formed in a polygonal shape, the assembling with the conducting module 200 may be easily performed, a gap between the thermoelectric module structure 100 and the conducting module 200 may not be generated, and the coupling with other thermoelectric module structure 100 via the conducting module 200 may be easily made.

In addition, the thermoelectric module structure 100 is formed in a polygonal shape and may have a plurality of four sides, in which one of the plurality of four sides is provided with positive terminals (+) and negative terminals (−) and each terminal is preferably disposed to be terminals belonging to different thermoelectric modules 110.

Therefore, at the time of the assembling of the conducting module 200 and the thermoelectric module structure 100, different thermoelectric modules 110 included in the thermoelectric module structure 100 are serially connected to each other depending on the form of the conducting module 200 and thus may be conducted to each other.

Further, since the positive terminal (+) and the negative terminal (−) belonging to one thermoelectric module 110 are positioned at different four sides and therefore one thermoelectric module 110 may be connected to at least two thermoelectric modules 110, such that extendibility and connectivity between the thermoelectric modules 110 may be improved.

Meanwhile, describing in more detail the conducting module 200, the conducting module 200 may have various conducting models. For example, as described above, one conducting model may have a form in which positive terminals (+) and negative terminals (−) of different thermoelectric modules 110 provided at a circumference portion of the thermoelectric module structure 100 are connected to each other. As illustrated in FIG. 2, in the case of a conducting module a which connects the thermoelectric modules 110 within the thermoelectric module structure 100, one side and the other side may be each coupled with different thermoelectric modules structures 100 and each surface is provided with a pair of terminals to be coupled with the positive terminal (+) or the negative terminal (−) of the thermoelectric module structure 100, preferably, the positive terminals (+) or the negative terminals (−) positioned on the same four sides, and the pair of terminals are connected to each other to be conducted to each other.

Each conducting line of one side and the other side of the conducting module 200a of the model is independently formed from each other and thus is preferably not conducted with each other.

In addition, another conducting model has a form in which the plurality of thermoelectric module structures 100 are conducted with each other. The thermoelectric module structures 100 are provided in plural and a conducting module 200b may connect between the positive terminals (+) and the negative terminals (−) which are provided in different thermoelectric module structures 100.

One side and the other side of the conducting module 200b of the model which are coupled with the thermoelectric module structure 100 are provided with a pair of terminals and terminals of one side and the other side corresponding to each other are connected to each other to be conducted to each other, such that the thermoelectric module structure 100 coupled with one side penetrates through the conducting module b to be conducted with the thermoelectric module structure 100 coupled with the other side.

The models of the conducting module 200 are only examples and may have different shapes and conducting arrangement forms depending on the shape of the thermoelectric module 110 or the thermoelectric module structure 100 and the terminal may also be implemented in various shapes depending on coupled terminals, a connection purpose, etc.

Further, the coupling between the thermoelectric module structure 100 and the conducting module 200 may be made using various coupling means such as bolting, bonding, locking coupling, and fastening. This may be variously set according to designer's intention.

Meanwhile, a connector 300 connecting between the terminal of the thermoelectric module structure 100 and the conducting module 200 is further provided, both ends of the connector 300 are each coupled with the terminal of the thermoelectric module structure 100 or the terminal of the conducting module 200, and at least any one of both ends may be detachably coupled with the thermoelectric module structure 100 or the conducting module 200.

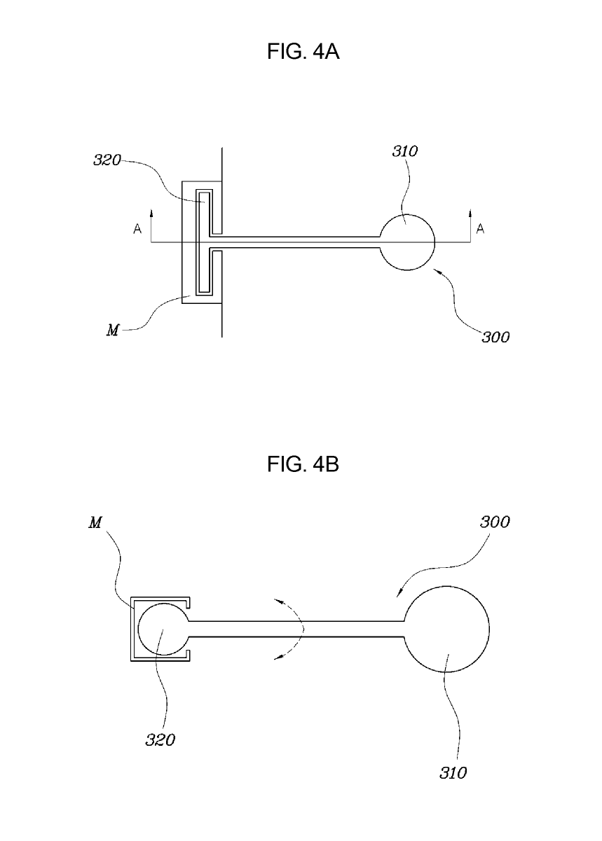

In detail, FIGS. 4A and 4B are diagrams illustrating a connector according to the exemplary embodiment of the present invention, in which FIG. 4A is a plan view and FIG. 4B is a cross-sectional view taken along A-A of FIG. 4A. As illustrated in FIGS. 4A and 4B, the connector 300 may be a conductible bar or wire or may be a conducting means which may be coupled with the thermoelectric module structure 100 and the conducting module 200 using a fastening means and may be configured in various forms.

Further, one end 310 of the connector 300 may be formed in a ball shape and the other end thereof may be formed in a T shape, such that the connector 300 may be rotatably coupled with the terminal of the thermoelectric module structure 100 or the terminal of the conducting module 200. Of course, the shapes of these ends are not necessarily limited to the foregoing and may be various formed.

The one end 310 of the connector 300 having a ball shape may be detachably coupled with the thermoelectric module structure 100 or the conducting module 200 and the other end thereof is not detached but may be formed to rotate based on a portion vertically branched to the length of the connector 300. The rotating direction may be a direction in which the thermoelectric module structure 100 forms a surface.

A terminal M coupled with the other end 320 of the connector 300 may be formed to contact the other end 320 of the connector 300 the while enclosing the other end 320 of the connector 300 in a housing form and the other end 320 may maintain the state in which the other end 320 is continuously coupled with the terminal M of the thermoelectric module structure 100 or the conducting module 200 over a relatively wide area independent of the detachment of the one end 310, thereby stably maintaining the coupling between the thermoelectric module structure 100 and the conducting module 200.

Meanwhile, the terminal M of the thermoelectric module structure 100 or the conducting module 200 into which the one end 310 of the connector 300 is inserted may be formed in a housing shape of which the one side is opened to accommodate and enclose one end of the connector 300.

To maintain the state in which the one end 310 of the connector 300 is inserted into the terminal of the thermoelectric module structure 100 or the terminal of the conducting module 200 at the time of the insertion while the one end 310 of the connector 300 being detached, the terminal M of the thermoelectric module structure 100 or the terminal M of the conducting module 200 into which the one end 310 of the connector 300 is inserted may be further provided with an elastic projection N which is deformed at the time of the insertion of the one end 310 of the connector 300, elastically recovered after the insertion and is then pressed to prevent the one end of the connector 300 from being separated.

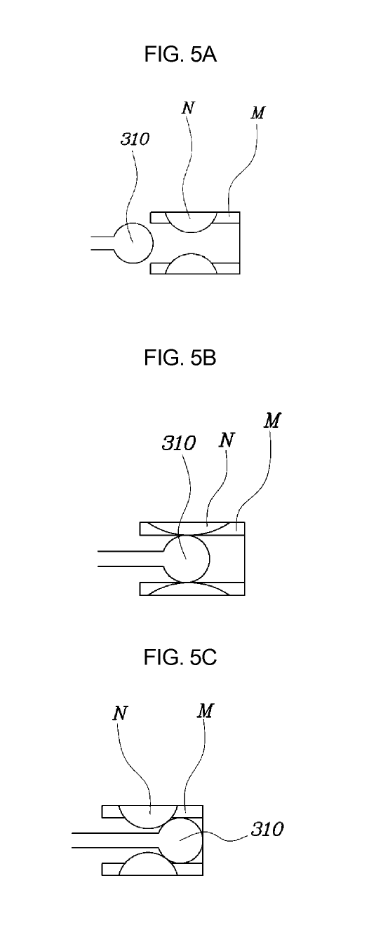

FIGS. 5A, 5B and 5C are diagrams illustrating a coupling appearance between the connector 300 and the terminal M, in which FIG. 5A illustrates an appearance before the insertion, FIG. 5B illustrates an appearance during the insertion, and FIG. 5C illustrates an appearance after the insertion. The fastening may be made only the simple insertion and as the one end 310 of the connector 300 is formed in a ball shape, various rotating angles may be formed between the connector 300 and the terminal M.

The elastic projection N may be configured to be expanded including an elastic material after the compression to press the one end 310 of the connector 300. Alternatively, the elastic projection N includes a separate elastic body like a spring to protrude to the inside of the terminal M and be compressed and expanded again. In addition to the necessary compressed and expanded deformation, a fastening force may be provided using elastic energy in various forms such as expansion, compression, bending, and recovery according to the designer's intention.

When the thermoelectric module structure 100 is coupled with the conducting module 200, it is preferable that the connector 300 may not be exposed to the outside or may be partially exposed.

According to the thermoelectric module assembly having the structure as described above, it is possible to assembly the thermoelectric modules in various forms by improving the assembling performance between the thermoelectric modules. For example, when the thermoelectric module structure has a quadrangular shape, all the four sides of the quadrangle may be coupled with different thermoelectric module structures, thereby implementing the extendibility of the assembling and the diversity of the configuration.

Further, by using the coupling using the conducting module, not the connection using the wire, the disconnection occurrence problem which has occur in the coupling between the thermoelectric modules using the typically exposed wire may be greatly reduced.

Further, since the connection is completed only by the coupling between the conducting modules and the thermoelectric module structure, the overall coupling system may be simple.

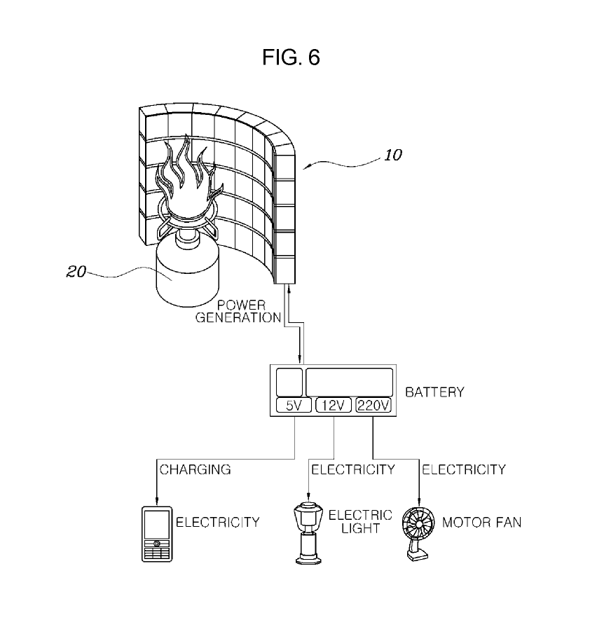

In addition, the bending may be made between the thermoelectric module structure and the conducting module at a predetermined angle due to the connector and thus the coupled assembly may have a smooth shape at the time of the coupling of the plurality of thermoelectric module structures. This may demonstrate the above effects when the thermoelectric module assembly 100 of the present application is installed around a heat source 20 to generate power as illustrated in FIG. 6 and in the case of absorbing heat using characteristics of the thermoelectric element to generate power, the thermoelectric module assembly 10 is configured to be enclosed around the heat source 20, thereby improving the power generation efficiency.

According to the thermoelectric module assembly having the structure as described above, it is possible to assembly the thermoelectric modules in various forms by improving the assembling performance between the thermoelectric modules.

Further, it is possible to lower the disconnection occurrence possibility between the thermoelectric modules.

For convenience in explanation and accurate definition in the appended claims, the terms “upper”, “lower”, “inner” and “outer” are used to describe features of the exemplary embodiments with reference to the positions of such features as displayed in the figures.

The foregoing descriptions of specific exemplary embodiments of the present invention have been presented for purposes of illustration and description. They are not intended to be exhaustive or to limit the invention to the precise forms disclosed, and obviously many modifications and variations are possible in light of the above teachings. The exemplary embodiments were chosen and described in order to explain certain principles of the invention and their practical application, to thereby enable others skilled in the art to make and utilize various exemplary embodiments of the present invention, as well as various alternatives and modifications thereof. It is intended that the scope of the invention be defined by the Claims appended hereto and their equivalents.

What is claimed is:

1. A thermoelectric module assembly, comprising:
a thermoelectric module structure including a plurality of thermoelectric elements continuously connected to one another and thermoelectric modules having positive terminals and negative terminals which are connected to the thermoelectric elements,
wherein the thermoelectric module is provided in plural and each of the thermoelectric modules is adjacently disposed to each other to have the positive terminals or the negative terminals provided along circumferential portions thereof.

2. The thermoelectric module assembly of claim 1, further comprising:
a conducting module coupled with the thermoelectric module structure and connect between the positive terminals (+) and the negative terminals (−) of the thermoelectric module.

3. The thermoelectric module assembly of claim 2, wherein the conducting module connects between the positive terminals and the negative terminals provided in a circumferential portion of the thermoelectric module structure.

4. The thermoelectric module assembly of claim 2, wherein the thermoelectric module structure is provided in plural and the conducting module connects between the positive terminals and the negative terminals provided in different thermoelectric module structures.

5. The thermoelectric module assembly of claim 2, further comprising:
a connector connecting between the terminal of the thermoelectric module and the conducting module, wherein both ends of the connector are each coupled with the terminal of the thermoelectric module or the terminal of the conducting module, and at least any one of both ends is detachably coupled with the thermoelectric module structure or the conducting module.

6. The thermoelectric module assembly of claim 5, wherein a first end of the connector is formed in a ball shape and the terminal of the thermoelectric module or the terminal of the conducting module into which the first end of the connector is inserted is formed in a housing shape of which a side is opened to accommodate and enclose the connector.

7. The thermoelectric module assembly of claim 5, wherein the terminal of the thermoelectric module or the terminal of the conducting module into which the first end of the connector is inserted is further provided with an elastic protrusion which is deformed at a time of the insertion of the first end of the connector, elastically recovered after the insertion, and then pressed to prevent the first end of the connector from being separated.

8. The thermoelectric module assembly of claim 5, wherein a second end of both ends of the connector is formed in a T shape and is rotatably coupled to the thermoelectric module terminal or the conducting module terminal.

9. The thermoelectric module assembly of claim 1, wherein the thermoelectric module structures are integrally formed by bonding side portions of each thermoelectric module to each other and have a polygonal circumferential portion, and one of a plurality of four sides is provided with the positive terminals and the negative terminals and each terminal is a terminal belonging to different thermoelectric modules.

10. The thermoelectric module assembly of claim 2, wherein the conducting module is coupled with the positive terminal and the negative terminal of the thermoelectric module structure and each terminal is terminals belonging to different thermal modules.
